(19) United States
(12) Patent Application Publication
(10) Pub. No.: US 2026/0361234 A1
(43) Pub. Date: Nov. 12, 2026

(54) Apparatus and Method for Integrating High Voltage Electrolytic Capacitors in Power Conversion Systems

(71) Applicant: AA Power Inc., Boston, MA (US)

(72) Inventor: Qun Lu, Lexington, MA (US)

(21) Appl. No.: 19/656,978

(22) Filed: Apr. 23, 2026

Related U.S. Application Data
(60) Provisional application No. 63/795,038, filed on Apr. 25, 2025.
(60) Provisional application No. 63/796,705, filed on Apr. 29, 2025.

(51) Int. Cl. H02M 7/12; H01G 11/08; H02J 7/34; H02M 7/00; H02M 7/217; H05K 7/14

(52) U.S. Cl. CPC H02M 7/125; H01G 11/08; H02J 7/345; H02M 7/003; H02M 7/2173; H05K 7/1492; H02J 2207/10; H02J 2207/50

(57) ABSTRACT

A power conversion system may include a power factor correction (PFC) rectifier configured to convert an AC input to a DC output, an AC bus connected between the AC input and the PFC rectifier, a DC/DC converter configured to generate a regulated DC output, a DC bus connected between an output of the PFC rectifier and an input of the DC/DC converter, and a high-voltage electrolytic capacitor (HVEC capacitor) configured to increase hold-up time during input disturbances and to absorb or release energy in response to load changes.

### PRIORITY

This application claims the benefit of U.S. Provisional Application No. 63/795,038, filed on Apr. 25, 2025, entitled “Apparatus and Method for Integrating High Voltage Electrolytic Capacitors in Power Conversion Systems” and U.S. Provisional Application No. 63/796,705, filed on Apr. 29, 2025, entitled “Apparatus and Method for Integrating High Voltage Electrolytic Capacitors in Power Conversion Systems,” each application is hereby incorporated herein by reference.

### TECHNICAL FIELD

The present disclosure relates generally to the field of power conversion systems, and in particular embodiments, to apparatus and method for integrating High Voltage Electrolytic Capacitor (HVEC capacitor) in power conversion systems.

### BACKGROUND

In the field of power conversion systems, electrolytic capacitors are widely used for energy storage, voltage smoothing, and transient buffering. Currently, the voltage rating of commonly used electrolytic capacitors is typically around 500V. However, in applications involving three-phase or high-voltage DC systems, capacitors with voltage ratings exceeding 500V are often required. In the past, to meet such high voltage demands, it was common to connect two electrolytic capacitors in series. Assuming the capacitance of a single capacitor is C, when two capacitors are connected in parallel, according to the parallel capacitance characteristic, the total capacitance equals the sum of the individual capacitances, i.e., the total capacitance is 2C. However, when these two capacitors are connected in series, the total capacitance can be calculated using the series capacitance formula shown below, resulting in Cseries=0.5C.

$$\frac{1}{{C}_{series}} = \frac{1}{C} + \frac{1}{C} = \frac{2}{C}$$

FIG. 1 illustrates a conventional Vienna rectifier, in which two capacitors, Cdc1 and Cdc2, are connected in series between the positive and negative output terminals. Cdc1 and Cdc2 are both rated at 400V. This architecture is widely used in three-phase AC to DC conversion systems for power factor correction (PFC).

FIG. 2 illustrates a conventional three-phase six-switch rectifier, in which two capacitors, Cdc1 and Cdc2, are connected in series between the positive and negative output terminals. Cdc1 and Cdc2 are both rated at 400V.

However, connecting capacitors in series not only reduces the capacitance to one-quarter of the original capacitance value (compared to the parallel connection), but also introduces increased internal resistance and voltage balancing issues. As a result, the performance, lifespan, and reliability of series-connected capacitors are inferior to those of single or parallel-connected capacitors.

FIG. 3 illustrates the structure of a conventional power supply unit (PSU), which comprises a power factor correction (PFC) rectifier, a capacitor Cdc, a DC/DC conversion stage, and a load. The PFC rectifier in the illustrated PSU architecture may be implemented using a Vienna rectifier, a six-switch three-phase rectifier, or a Swiss rectifier, depending on system requirements. The capacitor Cdc is positioned between the PFC and DC/DC stages and is configured to provide a hold-up time of approximately 20 milliseconds. To achieve this duration, conventional PSU designs typically require either a single large electrolytic capacitor or multiple electrolytic capacitors connected in parallel.

It is thus desirable to develop techniques and mechanisms to improve performance of fuel cell systems in various aspects, and to facilitate utilization of fuel cell systems.

### SUMMARY

Technical advantages are generally achieved, by embodiments of this disclosure which describe a hybrid electrolytic capacitor apparatus and method.

In accordance with one aspect of the present disclosure, a power conversion system is provided that includes: a power factor correction (PFC) rectifier configured to convert an AC input to a DC output, an AC bus connected between the AC input and the PFC rectifier, a DC/DC converter configured to generate a regulated DC output, a DC bus connected between an output of the PFC rectifier and an input of the DC/DC converter, and a high-voltage electrolytic capacitor (HVEC capacitor) configured to increase hold-up time during input disturbances and to absorb or release energy in response to load changes.

In accordance with another aspect of the present disclosure, a power conversion system comprises a DC bus configured to receive a DC voltage, a DC/DC converter configured to generate a regulated DC output, an input of the DC/DC converter being connected to the DC bus, and a HVEC capacitor module, which is configured by one or a plurality of parallel high-voltage electrolytic capacitors to increase hold-up time during input disturbances and to absorb or release energy in response to load changes.

In accordance with yet another aspect of the present disclosure, a power shelf system comprises a power factor correction (PFC) module configured to convert an AC input to a DC output, a DC/DC converter module configured to generate a regulated DC output, and an E-bank module comprising energy storage elements selected from the group consisting of a high-voltage electrolytic capacitor (HVEC capacitor), supercapacitor, battery and any combination thereof, configured to increase hold-up time during input disturbances and to absorb or release energy in response to load changes, wherein the PFC module, the DC/DC converter module, and the E-bank module reside in a housing.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a circuit diagram of a conventional Vienna rectifier, in which two DC capacitors are connected in series;

FIG. 2 is a circuit diagram of a conventional Three-phase Six-switch Rectifier, in which two DC capacitors are connected in series;

FIG. 3 illustrates the structure of a conventional power supply unit;

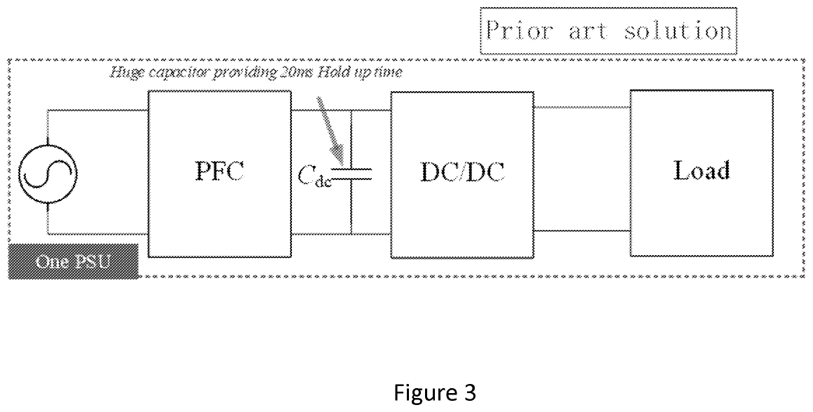

FIG. 4 illustrates an example Vienna rectifier circuit using an HVEC capacitor in accordance with various embodiments of the present disclosure;

FIG. 5 illustrates an example Three-phase Six-switch circuit using an HVEC capacitor in accordance with various embodiments of the present disclosure;

FIG. 6 is a block diagram illustrating an example power conversion system using an HVEC capacitor in accordance with various embodiments of the present disclosure;

FIG. 7 is a block diagram of an example power conversion system using an HVEC capacitor in accordance with various embodiments of the present disclosure;

FIG. 8 is a block diagram of an example power conversion system using an HVEC capacitor in accordance with various embodiments of the present disclosure;

FIG. 9 is a block diagram of an example power conversion system using an HVEC capacitor in accordance with various embodiments of the present disclosure;

FIG. 10 is a block diagram of an example power conversion system using an HVEC capacitor in accordance with various embodiments of the present disclosure;

FIG. 11 is a block diagram of an example power conversion system using an HVEC capacitor in accordance with various embodiments of the present disclosure;

FIG. 12 is a block diagram of an example power conversion system using an HVEC capacitor in accordance with various embodiments of the present disclosure;

FIG. 13 is a block diagram of an example power conversion system using an HVEC capacitor in accordance with various embodiments of the present disclosure;

FIG. 14 is a block diagram of an example power conversion system using an HVEC capacitor in accordance with various embodiments of the present disclosure;

FIG. 15 is a block diagram of an example power conversion system using an HVEC capacitor in accordance with various embodiments of the present disclosure;

FIG. 16 is a block diagram of an example power conversion system using an HVEC capacitor in accordance with various embodiments of the present disclosure;

FIG. 17 is a block diagram of an example power conversion system using an HVEC capacitor in accordance with various embodiments of the present disclosure;

FIG. 18 is a block diagram of an example power conversion system using an HVEC capacitor in accordance with various embodiments of the present disclosure;

FIG. 19 illustrate the structure of a power supply unit using an HVEC capacitor in accordance with various embodiments of the present disclosure;

FIG. 20 depicts a modular power supply architecture using HVEC capacitor(s) in accordance with various embodiments of the present disclosure;

FIG. 21 illustrates an example implementation of an E-bank module used in conjunction with a PSU in accordance with various embodiments of the present disclosure;

FIG. 22 illustrates an example of actual power shelf system in accordance with various embodiments of the present disclosure;

FIG. 23 is a block diagram illustrating the example power shelf system in FIG. 22 in accordance with various embodiments of the present disclosure; and

FIG. 24 illustrates an example Swiss rectifier circuit using an HVEC capacitor in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood within the scope of this disclosure. It is therefore intended that the appended claims encompass any such modifications or embodiments.

The present disclosure will be described with respect to preferred embodiments in a specific context, namely apparatus and method for integrating High Voltage Electrolytic Capacitor (HVEC capacitor) in power conversion systems. Hereinafter, various embodiments will be explained in detail with reference to the accompanying drawings.

In applications involving three-phase or high-voltage DC systems, capacitors with voltage ratings exceeding 500V are often required. The HVEC capacitors used in the present disclosure have a voltage rating ranging from 700V to 1200V. Compared to conventional capacitors with a voltage rating of approximately 500V, the HVEC capacitors have a similar size when the capacitance value is the same.

To further illustrate the advantages of the HVEC capacitors, a comparison of the energy storage capacity between 400V and 800V capacitors is provided. According to the energy storage formula for capacitors,

E=½CV²

(where E is the stored energy, C is the capacitance, and V is the voltage), when the capacitance C remains constant, the energy stored in a 400V capacitor is

E₄₀₀=0.5×400²×C.

The energy stored in an 800V capacitor is

E₈₀₀=0.5×800²×C.

By calculating the ratio of their stored energies, i.e.,

$$\frac{{E}_{800}}{{E}_{400}} = \frac{{800}^{2}}{{400}^{2}} = 4 ,$$

it is clear that, for the same capacitance value, an 800V capacitor stores four times more energy than a 400V capacitor. This illustrates the principle behind enhancing energy storage density using the HVEC capacitors in the present disclosure. In high-voltage applications, because the HVEC capacitors of the present disclosure have a high voltage rating, there is no longer a need to connect multiple low-voltage capacitors in series as was previously required.

The HVEC capacitors can be used individually or connected in parallel according to actual requirements. This configuration effectively avoids the capacitance reduction problem caused by series connection. As a result, the usable capacitance of the configurations using HVEC capacitors in the present disclosure can reach approximately four times that of conventional capacitors using series connection schemes, greatly expanding the range of applications and enabling a wide variety of application scenarios.

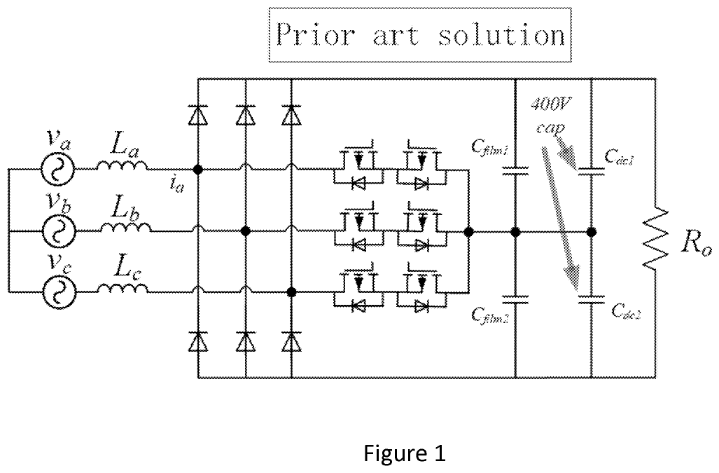

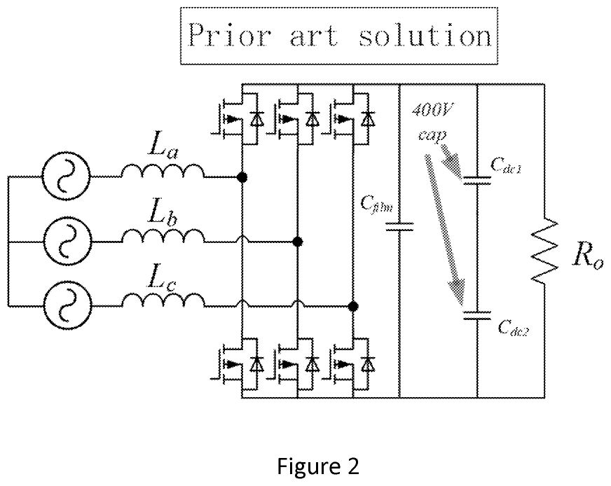

In three-phase rectification and inversion systems, there is typically a DC bus with a voltage around 800V. The DC bus refers to the high-voltage line between the rectifier's positive and negative output terminals, across which energy storage capacitors are connected. The DC bus has a positive terminal at 400V and a negative terminal at −400V. Compared to the prior art solution of connecting two 400V electrolytic capacitors in series, as illustrated in FIGS. 1 and 2, the present disclosure can directly integrate the HVEC capacitor into the DC bus. The HVEC capacitor solution in the present disclosure eliminates the capacitor voltage balancing issue, results in a smaller capacitor volume, and offers better reliability and lifespan than the conventional low-voltage series connection method. Additionally, the HVEC capacitor solution in the present disclosure enables functions such as lightning protection, voltage stabilization, and providing hold-up time. Its energy density can reach more than four times that of the conventional solutions.

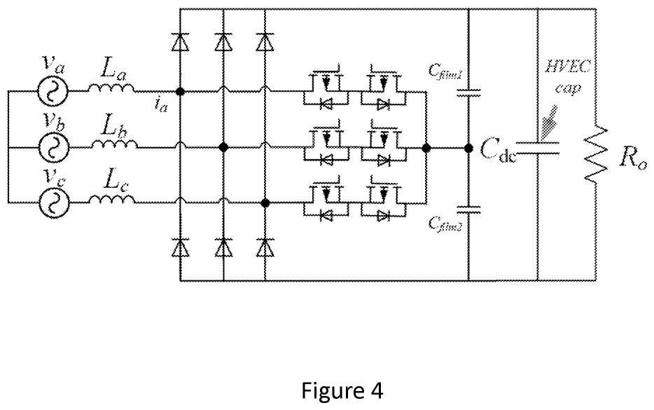

FIG. 4 illustrates an example Vienna rectifier circuit using an HVEC capacitor in accordance with various embodiments of the present disclosure. As shown in FIG. 4, the HVEC capacitor (Cdc) is directly connected across the positive and negative terminals of the DC bus. In some embodiments, the DC bus has a positive terminal at 400V and a negative terminal at −400V, and the HVEC capacitor has a voltage rating of 800V.

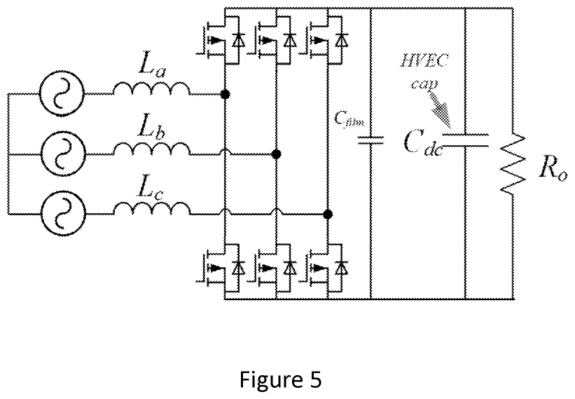

FIG. 5 illustrates an example Three-phase Six-switch circuit using an HVEC capacitor in accordance with various embodiments of the present disclosure. As illustrated in FIG. 5, the HVEC capacitor (Cdc) is directly connected across the positive and negative terminals of the DC bus. In some embodiments, the DC bus has a positive terminal at 400V and a negative terminal at −400V, and the HVEC capacitor has a voltage rating of 800V.

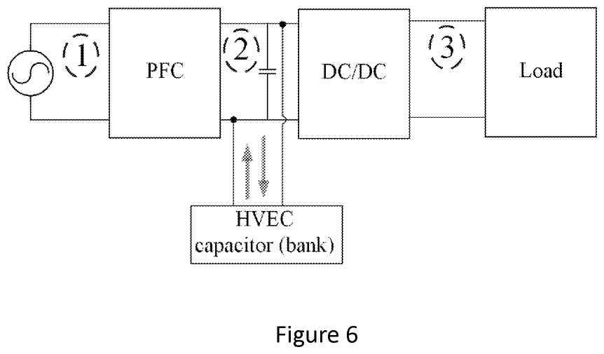

In server power supply applications and similar scenarios, Power Supply Units (PSUs) are typically required to provide a hold-up time of 20 ms. Currently, to meet this requirement, a common practice is to stack a large number of electrolytic capacitors on the DC bus. For example, in server AC power applications, electrolytic capacitors capable of providing 2-3 ms of hold-up time on the DC bus under normal conditions are sufficient to ensure the PSU's proper operation. However, in extreme situations such as input grid fluctuations or abnormal load changes, the power conversion system may require a hold-up time as long as 20 ms to maintain stable and continuous operation. In view of this, the present disclosure provides a solution in which conventional electrolytic capacitors are stacked on the DC bus to provide only 2-3 ms of hold-up time to maintain PSU operation under normal conditions. Simultaneously, a high energy density capacitor bank comprising HVEC capacitor(s) is introduced to address extreme operating conditions, providing an additional 17-18 ms of hold-up time. In some embodiments, the HVEC capacitor(s) may be integrated within the PSU to deliver the required energy throughout the entire hold-up period. The HVEC electrolytic capacitor(s) may be placed inside the PSU to supply the necessary energy for the entire hold-up duration. Regarding the integration methods for HVEC capacitor(s) into the power conversion system, there are a total of 13 approaches according to various embodiments of the present disclosure. In practical applications, these 13 integration methods can be optimized based on specific circumstances by referring to FIGS. 6 through 18, thereby selecting the most suitable integration scheme.

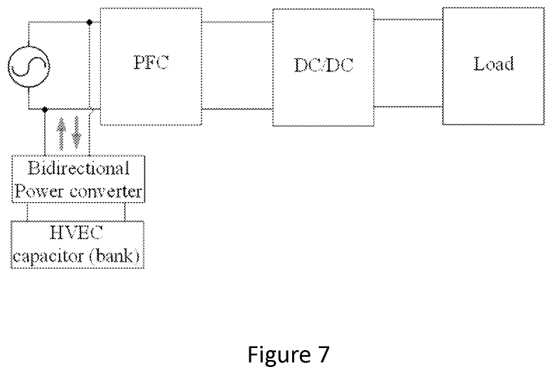

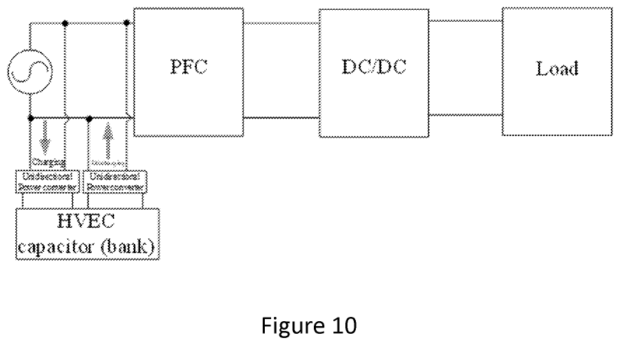

The thirteen integration methods for connecting HVEC capacitor(s) to the power conversion system can be classified into three categories: (1) Direct Connection, as illustrated in FIG. 6; (2) Connection via a Bidirectional Converter, as illustrated in FIGS. 7 through 9; and (3) Connection via Two Single-Phase Converters, as illustrated in FIGS. 10 through 18.

FIG. 6 is a block diagram illustrating an example power conversion system using an HVEC capacitor in accordance with various embodiments of the present disclosure. As illustrated in FIG. 6, the HVEC capacitor (Cdc) may be connected directly to the power conversion system without passing through a converter. The power conversion system shown in FIG. 6 comprises an AC power source, an AC bus (labeled as 1 in FIG. 6), a PFC rectifier, a low-capacitance capacitor, an HVEC capacitor, a DC bus (labeled as 2 in FIG. 6), a DC/DC converter, a DC output (labeled as 3 in FIG. 6), and a load. The AC power source can be single-phase or three-phase AC. The PFC rectifier may be implemented using various topologies, such as a Vienna rectifier, a six-switch boost rectifier, or a SWISS rectifier.

This power conversion system has three interfaces where electrolytic capacitor(s) can be connected, namely the AC bus (marked 1), the DC bus (marked 2), and the DC output terminal (marked 3).

In the Direct Connection configuration, an HVEC capacitor can only be connected to the DC bus. As illustrated in FIG. 6, the HVEC capacitor is connected in parallel to the output of the PFC rectifier, replacing the two series-connected DC capacitors used in conventional rectifier topologies. To improve the capacitor's energy utilization for hold-up time, methods such as increasing the DC bus voltage or using a wide-input-range DC/DC converter can be employed. When the HVEC capacitor is used for the power smoothing function, its stored energy can be adjusted by varying the DC bus voltage: raising the DC bus voltage causes the HVEC capacitor to absorb energy, while lowering the DC bus voltage causes the HVEC capacitor to release energy. The advantage of this Direct Connection method is that it requires no converter for system integration. However, its drawback is relatively lower energy utilization efficiency of the HVEC capacitor.

In the Connection via a Bidirectional Converter configuration, an HVEC capacitor may be connected to the power conversion system through a bidirectional converter, as shown in FIGS. 7-9. There are three possible connection points for the bidirectional converter: the AC bus, the DC bus, and the DC output terminal. The Connection via a Bidirectional Converter method significantly improves the energy utilization efficiency of the HVEC capacitor. However, the control principle for charging and discharging the HVEC capacitor is more complex.

FIG. 7 is a block diagram of an example power conversion system using an HVEC capacitor in accordance with various embodiments of the present disclosure. As illustrated in FIG. 7, a bidirectional power converter is connected between the AC power source and an HVEC capacitor (bank). The bidirectional converter enables controlled energy flow between the AC power source and the HVEC capacitor, supporting peak-shaving, energy buffering, and potential grid support functionalities, in accordance with various embodiments of the present disclosure.

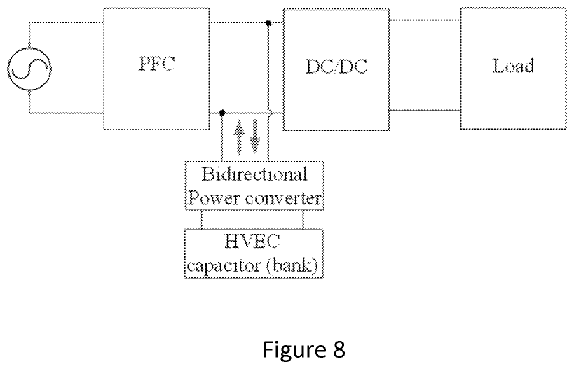

FIG. 8 is a block diagram of an example power conversion system using an HVEC capacitor in accordance with various embodiments of the present disclosure. As illustrated in FIG. 8, a bidirectional power converter is connected between the output of the PFC rectifier and an HVEC capacitor (bank). Unlike prior architectures where the bidirectional converter interfaces with the AC power source, this configuration enables energy buffering and bidirectional energy control directly at the intermediate DC stage, improving voltage stability, load response, and energy reuse efficiency in accordance with various embodiments of the present disclosure.

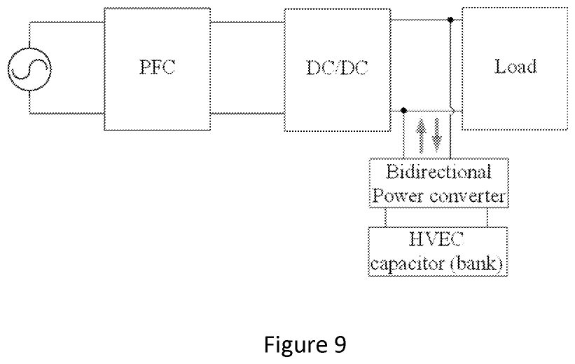

FIG. 9 is a block diagram of an example power conversion system using an HVEC capacitor in accordance with various embodiments of the present disclosure. As illustrated in FIG. 9, a bidirectional power converter is connected between the output of the DC/DC converter and an HVEC capacitor (bank). This configuration enables bidirectional energy flow between the HVEC capacitor (bank) and the load side, allowing for advanced functions such as energy buffering, load balancing, and transient voltage stabilization.

In the Connection via Two Single-Phase Converters configuration, the HVEC capacitor may be connected to the power conversion system through two single-phase converters (a charging converter and a discharging converter), as shown in FIGS. 10-18. Both the charging and discharging converters can be connected to the AC bus, DC bus, or DC output terminal, resulting in 3×3=9 possible connection methods. These methods offer high capacitor energy utilization efficiency and the simplest control for charging and discharging, but the single-phase converters may be relatively large in size.

During normal operation, the load is powered by the AC power source. When the AC power source fails, the electrolytic capacitor(s) supply power to the load to provide hold-up time. The HVEC capacitor does not operate continuously; it only activates when the AC power source fails and hold-up time is needed, which is an infrequent occurrence during normal power operation.

FIG. 10 is a block diagram of an example power conversion system using an HVEC capacitor in accordance with various embodiments of the present disclosure. As illustrated in FIG. 10, both the charging converter and the discharging converter are connected to the AC bus.

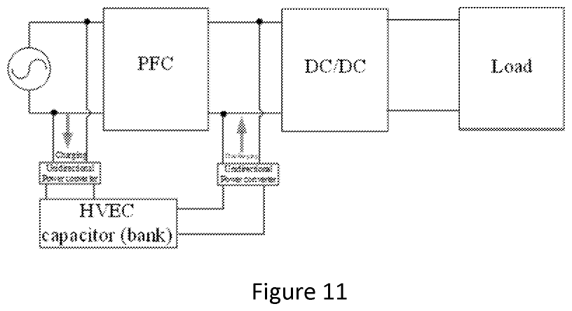

FIG. 11 is a block diagram of an example power conversion system using an HVEC capacitor in accordance with various embodiments of the present disclosure. As illustrated in FIG. 11, The charging converter is connected to the AC bus, and the discharging converter is connected to the DC bus.

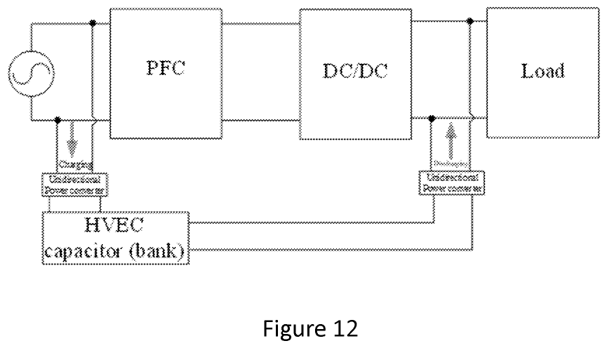

FIG. 12 is a block diagram of an example power conversion system using an HVEC capacitor in accordance with various embodiments of the present disclosure. As illustrated in FIG. 12, the charging converter is connected to the AC bus, and the discharging converter is connected to the DC output terminal.

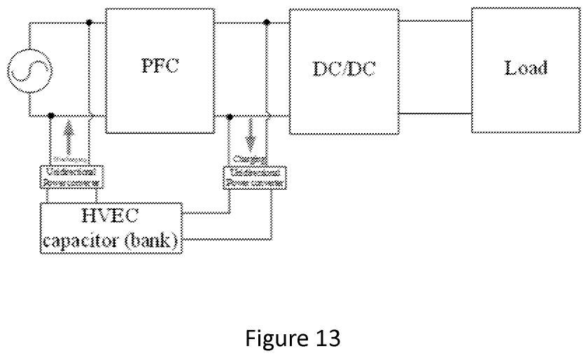

FIG. 13 is a block diagram of an example power conversion system using an HVEC capacitor in accordance with various embodiments of the present disclosure. As illustrated in FIG. 13, the charging converter is connected to the DC bus, and the discharging converter is connected to the AC bus.

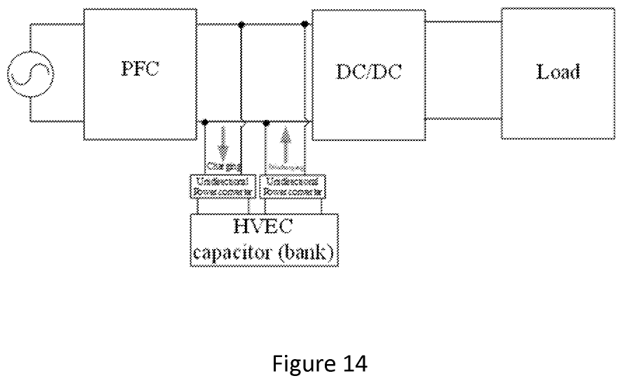

FIG. 14 is a block diagram of an example power conversion system using an HVEC capacitor in accordance with various embodiments of the present disclosure. As illustrated in FIG. 14, both the charging converter and the discharging converter are connected to the DC bus.

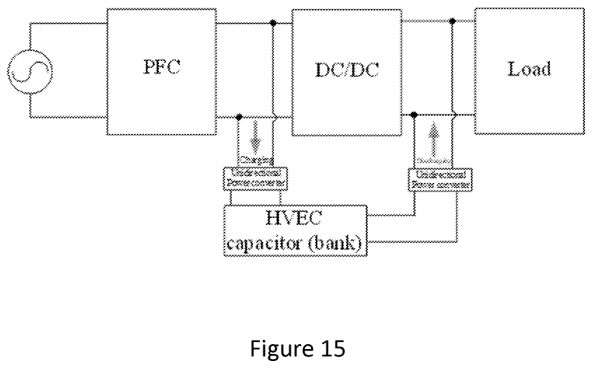

FIG. 15 is a block diagram of an example power conversion system using an HVEC capacitor in accordance with various embodiments of the present disclosure. As illustrated in FIG. 15, the charging converter is connected to the DC bus, and the discharging converter is connected to the DC output terminal.

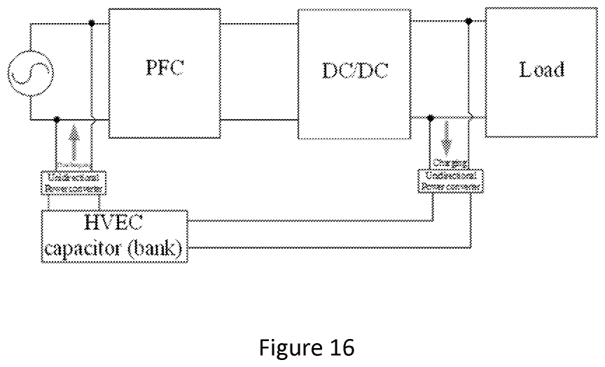

FIG. 16 is a block diagram of an example power conversion system using an HVEC capacitor in accordance with various embodiments of the present disclosure. As illustrated in FIG. 16, the charging converter is connected to the DC output terminal, and the discharging converter is connected to the AC bus.

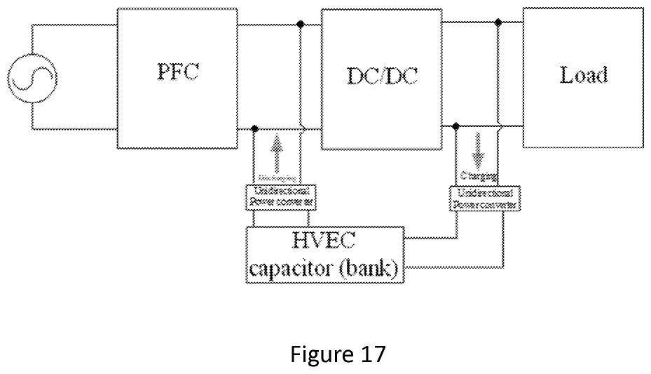

FIG. 17 is a block diagram of an example power conversion system using an HVEC capacitor in accordance with various embodiments of the present disclosure. As illustrated in FIG. 17, the charging converter is connected to the DC output terminal, and the discharging converter is connected to the DC bus.

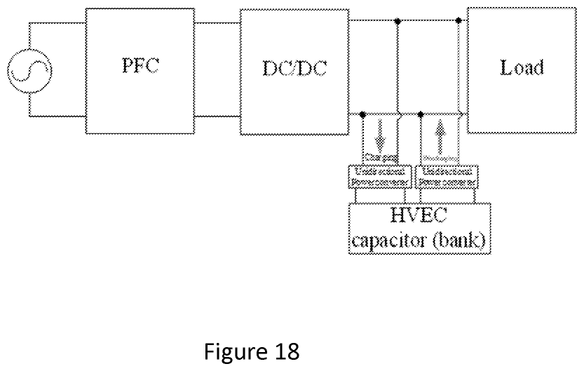

FIG. 18 is a block diagram of an example power conversion system using an HVEC capacitor in accordance with various embodiments of the present disclosure. As illustrated in FIG. 18, both the charging converter and the discharging converter are connected to the DC output terminal.

In server power supply applications and similar scenarios, PSU is responsible for providing sufficient hold-up time for the power conversion system, typically around 20 ms. In traditional practice, a large number of electrolytic capacitors are usually connected in parallel on the DC bus to meet the system's hold-up time requirements.

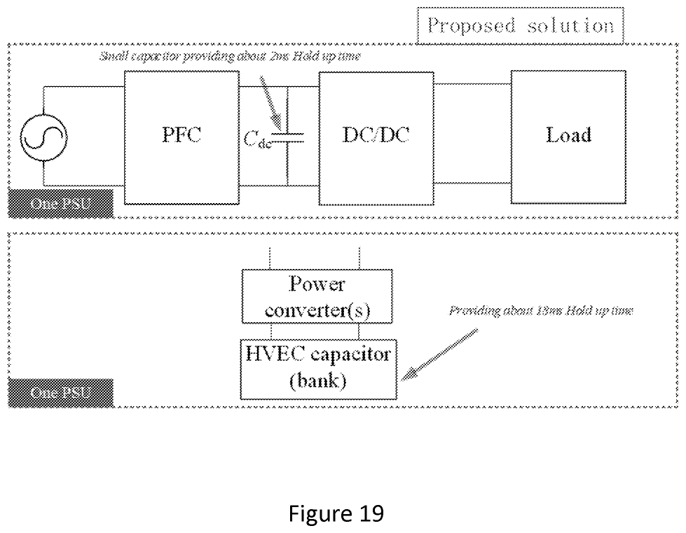

According to another embodiment of the present disclosure, the PSU can be equipped with capacitors that provide about 2 ms of hold-up time, while the remaining energy demand is fulfilled by an energy pack composed of HVEC capacitor(s) placed outside the PSU. FIG. 19 illustrates the structure of a PSU architecture using an HVEC capacitor in accordance with various embodiments of the present disclosure. As illustrated by FIG. 19, this energy pack is located outside the PSU and is electrically coupled to the system through one or more power converters. The HVEC capacitor(s) may provide about 18 ms hold up time.

By adopting this external energy pack approach, the PSU can use capacitors with smaller capacitance. Since the capacitor volume is greatly reduced, the power density of the PSU can be significantly improved. In terms of operation, the external HVEC capacitor pack functions similarly to common scenarios. When the system operates normally, the load is powered by the AC power source. Once input grid fluctuations cause instability in the power conversion system, the external HVEC capacitor bank immediately activates to supply power. This HVEC capacitor pack only starts working when the AC power source fails, which is an infrequent event during normal operation.

In Graphics Processing Units (GPUs) and Tensor Processing Units (TPUs) computing systems, the simultaneous switching on and off of a large number of GPUs/TPUs causes severe load fluctuations. When the load power of GPUs/TPUs experiences sudden increases or decreases, the power drawn from the AC power supply also fluctuates sharply. This can easily trigger the uninterruptible power supply (UPS) on the AC power side and, in more extreme cases, lead to instability or faults in the power supply network. To address this issue, the present disclosure utilizes an energy pack composed of HVEC electrolytic capacitors. When the GPU/TPU power suddenly increases, the energy pack releases energy; when the power suddenly decreases, the energy pack absorbs energy. This smooths the changes in input power from the AC supply, preventing shocks to the UPS and the power network at the input side. The method of integrating this energy pack into the rectifier system is consistent with previous systems, with three categories and a total of 13 connection schemes as shown in FIGS. 6 to 18. The operating mode is that under normal conditions, power is supplied by the AC source; when the load power suddenly increases, the energy pack releases energy; when the load power suddenly decreases, the energy pack absorbs energy.

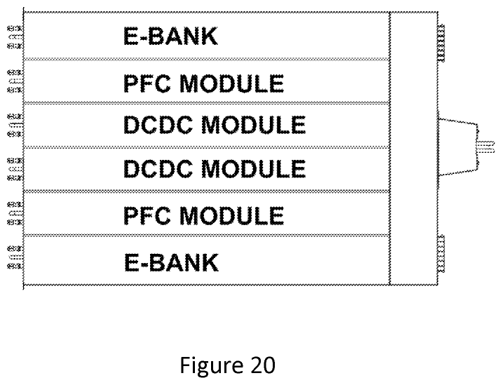

HVEC capacitor(s) may be assembled into a separate module or shelf (E-bank), as shown in FIG. 20. FIG. 20 depicts a modular power supply architecture in which the traditional AC/DC power supply is split into modular form, offering advantages such as flexibility and scalability, reduced maintenance costs, improved production and testing efficiency, and enhanced fault tolerance and reliability. As illustrated in FIG. 20, the modular power supply architecture may comprise one or more E-bank modules, one or more DC/DC modules, and one or more PFC modules. The E-bank modules, composed of HVEC capacitors, are designed to supplement the hold-up time of the power conversion system. These modules may be stacked within a unified enclosure or housing. Regarding the integration methods for the HVEC electrolytic capacitor(s) with this modular design, there are a total of 13 connection schemes across three categories, as illustrated in FIGS. 6 to 18.

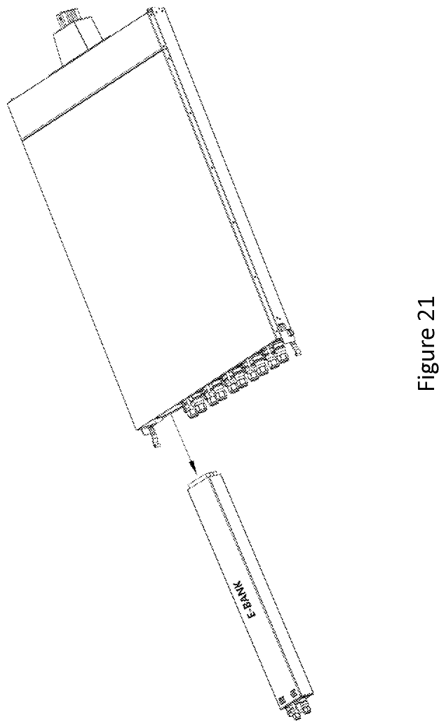

FIG. 21 illustrates an example implementation of an E-bank module used in conjunction with a PSU in accordance with various embodiments of the present disclosure. The E-bank module, composed of HVEC capacitors, is shown as a module that connects externally to the PSU via a dedicated interface. This modular configuration enables convenient installation, replacement, or upgrading of the energy storage component without requiring disassembly of the PSU enclosure. Such a design enhances serviceability, simplifies maintenance, and allows for scalable energy storage depending on system requirements.

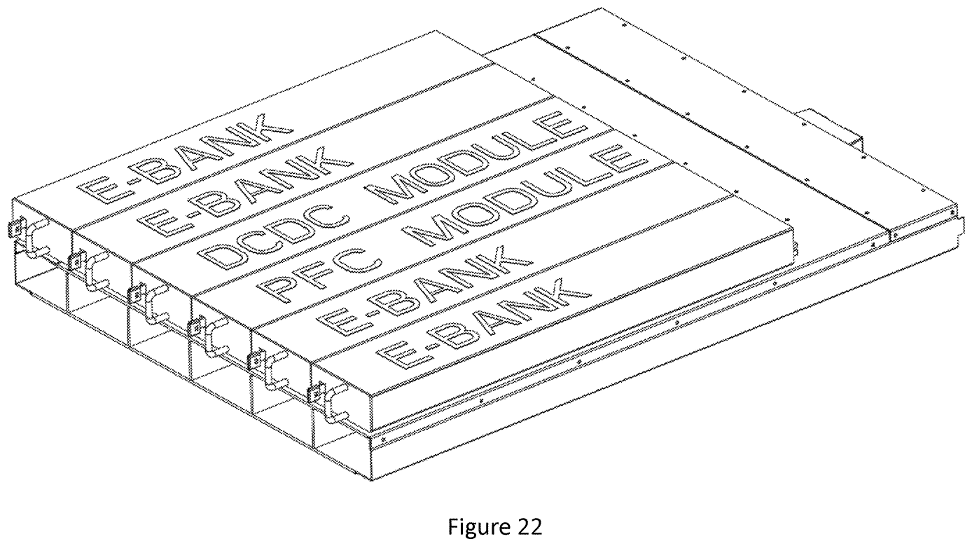

FIG. 22 illustrates an example of actual power shelf system. As illustrated in FIG. 22, the power shelf system comprises a PFC module, a DC/DC module, and four parallel-connected E-banks on the DC bus. Although four E-banks are illustrated in FIG. 22, other quantities may be used depending on system needs.

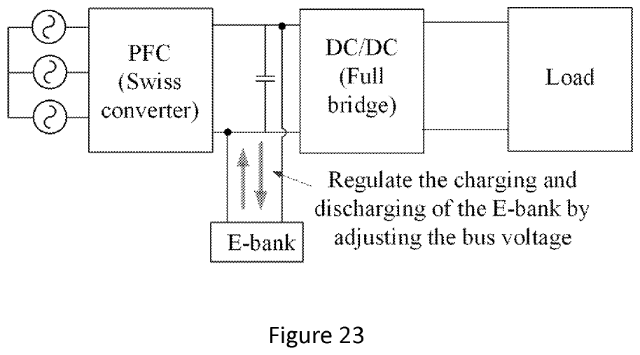

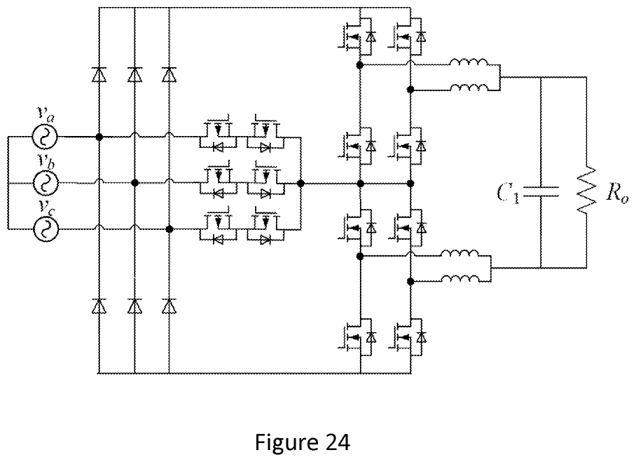

FIG. 23 is a block diagram illustrating the example power shelf system in FIG. 22 in accordance with various embodiments of the present disclosure. The power shelf system comprises a PFC module, a DC/DC converter module, E-bank(s), and a load. Each E-bank may contain a 450 V, 47.6 mF capacitor. In the illustrated embodiment, four E-banks are connected in parallel on the DC bus, resulting in a total effective capacitance of 190.4 mF (4×47.6 mF). In some embodiments, the PFC module of the power shelf system utilizes a Swiss rectifier topology, as illustrated in FIG. 24. The E-bank may also be implemented with other PFC topologies, such as Vienna rectifiers or six-switch rectifiers, as described in earlier embodiments. The DC/DC converter module may incorporate a wide input voltage range topology (e.g., full-bridge converter topology). The E-bank(s) are charged and discharged by adjusting the DC bus voltage. The system regulates energy flow by dynamically adjusting the DC bus voltage between 200V and 400V. The Swiss rectifier functions as a buck-type PFC circuit, enables flexible DC bus voltage adjustment within the 200-400V range. The DC/DC converter maintains a stable 50 V output despite the wide input voltage variation (e.g. 200-400V).

FIG. 24 illustrates an example Swiss rectifier circuit using an HVEC capacitor in accordance with various embodiments of the present disclosure. As illustrated in FIG. 24, the HVEC capacitor is connected across the positive and negative terminals of the DC bus, replacing the two series-connected DC capacitors used in conventional Swiss rectifier topologies. In some embodiments, the DC bus has a positive terminal at 400V and a negative terminal at −400V, and the HVEC capacitor has a voltage rating of 800V.

The E-bank configuration enables two critical operational capabilities: a hold-up time function, which ensures uninterrupted power delivery during input disturbances, and a power smoothing function, which mitigates fluctuations in the DC bus voltage by dynamically absorbing or releasing energy as needed.

Under normal operation, the AC grid supplies power to the load. During grid disturbances or outages, the E-bank modules provide backup energy to sustain load operation. The hold-up time can be calculated using the following formula:

$${t}_{h o l d} = \frac{0.5 C ( {U}_{max}^{2} - {U}_{min}^{2} )}{{P}_{shelf}} = 228 ms$$

where: C is the total capacitance of the E-bank modules, Umax is the maximum DC bus voltage (e.g., 400 v), Umin is the minimum allowable DC bus voltage during discharge (e.g., 200 v), Pshelf is output power of the power shelf. For example, if Pshelf is 50 kW, and the E-bank has a total capacitance of 190.4 mF with a DC bus voltage range of 400 V to 200 V, the calculated hold-up time is approximately 228 ms. Note that the 50-kW output power value is provided as an illustrative example. The actual power Pshelf may vary depending on system design and application requirements, which will result in different calculated hold-up times accordingly. The DC/DC converter's wide input range (e.g. 200-400V) ensures stable 50 V output even as the bus voltage decays from 400V to 200V.

The E-banks mitigate load transients by releasing energy during sudden load increases and absorbing energy during load decreases. For example, E-banks can release stored energy in response to power surges from GPUs or TPUs, and absorb energy when GPU/TPU power drop. This smoothing action reduces input power fluctuations, protecting UPS and the grid, as illustrated in FIG. 25.

FIG. 25 is a timing diagram illustrating the power-smoothing function of the E-bank modules in accordance with various embodiments of the present disclosure. FIG. 25 illustrates the input power of the Power shelf (red line), the load power (green line), and the energy contribution from the E-bank capacitor modules (dashed line). The figure shows how the E-bank mitigates power transients by dynamically releasing or absorbing energy to maintain stable load power.

As illustrated in FIG. 25, before time t1, the power shelf system operates under normal conditions, where both the input power of the power shelf and the load power remain constant at 50 kW. No intervention from the E-bank is required.

As time t1, the load power drops from 50 kw to 0 kw. From time t1 to t2, the system operates under an energy absorption phase, during which the E-bank modules absorb the excess energy, as indicated by the dashed lines. The DC bus voltage rises from 200V to 400V as the E-bank modules absorb excess energy. The input power of the power shelf decreases linearly during the period of t1-t2, instead of dropping abruptly.

At time t2, the input power of the power shelf decreases to 0 kw, and the E-bank modules stop absorbing energy.

The smoothing time can be calculated using the following formula:

$${t}_{smooth} = \frac{0.5 C ( {U}_{max}^{2} - {U}_{min}^{2} )}{{P}_{c}} = 456 ms$$

where: C is the total capacitance of the E-bank modules, Umax is the maximum DC bus voltage (e.g., 400 v), Umin is the minimum allowable DC bus voltage during discharge (e.g., 200 v), Pc is the average capacitor power which equals to 0.5*Pshelf. For example, if Pshelf is 50 kW, C=190.4 mF, Uₘₐₓ=400V, Uₘᵢₙ=200V, P_{c}=0.5*P_{shelf}=25 KW, then the calculated Smoothing time is approximately 456 ms.

At time t3, the load power suddenly increases from 0 kw to 50 kw. During time t3 to t4, the power shelf system operates under an energy release phase. The DC bus voltage decreases as the E-bank modules discharge stored energy to support the rising load. The input power of the power shelf ramps up linearly from 0 kW to 50 kW during this period, instead of increasing abruptly. The E-bank modules release stored energy to fill the gap between the rising load and the initially low input from the power shelf, ensuring uninterrupted power delivery and smoothing the system's response. Similar calculation yields identical smoothing time: 456 ms.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed:

1. A power conversion system, comprising:
a three-phase power factor correction (PFC) rectifier configured to convert an AC input to a DC output;
an AC bus connected between the AC input and the PFC rectifier;
a DC/DC converter configured to generate a regulated DC output;
a DC bus connected between an output of the PFC rectifier and an input of the DC/DC converter; and
a HVEC capacitor module, which is configured by one or a plurality of parallel high-voltage electrolytic capacitors to increase hold-up time during input disturbances and to absorb or release energy in response to load changes.

2. The power conversion system of claim 1, wherein the HVEC capacitor module is directly connected to the DC bus, and stored energy of the HVEC capacitor module is adjusted by varying a voltage of the DC bus.

3. The power conversion system of claim 2, wherein the PFC rectifier is a Vienna rectifier or other boost-type rectifier.

4. The power conversion system of claim 2, wherein the PFC rectifier is a Swiss rectifier or other buck-type rectifier.

5. The power conversion system of claim 2, wherein the PFC rectifier is a buck-boost-type rectifier.

6. The power conversion system of claim 1, further comprising a bidirectional power converter, wherein the bidirectional power converter is connected between the AC input and the HVEC capacitor module.

7. The power conversion system of claim 1, further comprising a bidirectional power converter, wherein the bidirectional power converter is connected between the DC bus and the HVEC capacitor module.

8. The power conversion system of claim 1, further comprising a bidirectional power converter, wherein the bidirectional power converter is connected between an output of the DC/DC converter and the HVEC capacitor module.

9. The power conversion system of claim 1, further comprising a charging converter and a discharging converter, wherein the HVEC capacitor module is configured to be charged by the charging converter and to discharge energy by the discharging converter.

10. The power conversion system of claim 4, wherein the DC/DC converter is configured to receive a wide input voltage range, and a ratio of a maximum input voltage to a minimum input voltage of the DC/DC converter is at least 2 times.

11. The power conversion system of claim 10, wherein the DC/DC converter is a Dual Active Bridge (DAB) converter, and the PFC rectifier is a Swiss rectifier.

12. A power conversion system, comprising:
a DC bus configured to receive a DC voltage;
a DC/DC converter configured to generate a regulated DC output, an input of the DC/DC converter being connected to the DC bus; and
a HVEC capacitor module, which is configured by one or a plurality of parallel high-voltage electrolytic capacitors to increase hold-up time during input disturbances and to absorb or release energy in response to load changes.

13. The power conversion system of claim 12, further comprising a bidirectional power converter, wherein the bidirectional power converter is connected between the DC bus and the HVEC capacitor module.

14. The power conversion system of claim 12, further comprising a bidirectional power converter, wherein the bidirectional power converter is connected between an output of the DC/DC converter and the HVEC capacitor module.

15. The power conversion system of claim 12, further comprising a charging converter and a discharging converter, wherein the HVEC capacitor module is configured to be charged by the charging converter and to discharge energy by the discharging converter.

16. A power shelf system, comprising:
a power factor correction (PFC) module configured to convert an AC input to a DC output;
a DC/DC converter module configured to generate a regulated DC output; and
an E-bank module comprising energy storage elements selected from the group consisting of a high-voltage electrolytic capacitor (HVEC capacitor), supercapacitor, battery and any combination thereof, configured to increase hold-up time during input disturbances and to absorb or release energy in response to load changes, wherein the PFC module, the DC/DC converter module, and the E-bank module reside in a housing.

17. The power shelf system of claim 16, wherein the DC/DC converter module comprises a Dual Active Bridge (DAB) converter, and the PFC module comprises a Swiss rectifier or other buck-type rectifier.

18. The power shelf system of claim 16, wherein the DC/DC converter module comprises a Full Bridge converter, and the PFC module comprises a Swiss rectifier or other buck-type rectifier.

19. The power shelf system of claim 16, wherein the HVEC capacitor module is an independent prepacked component module formed by one or a plurality of parallel high-voltage electrolytic capacitors.
